(19) United States
(12) Patent Application Publication
(10) Pub. No.: US 2022/0256675 A1
(43) Pub. Date: Aug. 11, 2022

(54) LIGHT SOURCE DEVICE

(71) Applicant: KYOCERA Corporation, Kyoto-shi, Kyoto (JP)

(72) Inventors: Toshifumi HIGASHI, Kirishima-shi (JP); Youji FURUKUBO, Kirishima-shi (JP); Takafumi YAMAGUCHI, Kirishima-shi (JP); Yuji IINO, Shibushi-shi (JP)

(73) Assignee: KYOCERA Corporation, Kyoto-shi, Kyoto (JP)

(21) Appl. No.: 17/620,454

(22) PCT Filed: Jun. 17, 2020
(86) PCT No.: PCT/JP2020/023722

§ 371 Date: Dec. 17, 2021

(30) Foreign Application Priority Data
Jun. 21, 2019 (JP) 2019-115145

(51) Int. Cl. H05B 47/16

(52) U.S. Cl. CPC H05B 47/16

(57) ABSTRACT

A light source device includes a plurality of light emitting unit portions including a light emitting element, a flashing circuit configured to cause the light emitting element to flash, and a delay circuit configured to control a timing at which the flashing circuit causes the light emitting element to flash. The delay circuit includes a resistor and a capacitor. At least two light emitting unit portions are connected to each other in parallel. At least one of a resistance value of the resistor and a capacitance value of the capacitor differs among the at least two light emitting unit portions connected to each other in parallel.

### TECHNICAL FIELD

The disclosed embodiments relate to a light source device.

### BACKGROUND ART

A light source device in which a plurality of light emitting elements such as laser diodes are mounted is known (for example, see Patent Document 1).

### CITATION LIST

### Patent Literature

Patent Document 1: JP 2016-51755 A

### SUMMARY OF INVENTION

The light source device according to an aspect of the embodiment includes a plurality of light emitting unit portions each including a light emitting element, a flashing circuit configured to cause the light emitting element to flash, and a delay circuit configured to control a timing at which the flashing circuit causes the light emitting element to flash. The delay circuit includes a resistor and a capacitor. At least two of the light emitting unit portions are connected to each other in parallel. At least one of a resistance value of the resistor and a capacitance value of the capacitor differs among the at least two of the light emitting unit portions connected to each other in parallel.

### BRIEF DESCRIPTION OF DRAWINGS

FIG. 1 is a perspective view illustrating a configuration of a light source device according to an embodiment.

FIG. 2 is a circuit diagram illustrating a configuration of an entire light source device according to the embodiment.

FIG. 3 is a circuit diagram illustrating a configuration of a light emitting unit portion according to the embodiment.

FIG. 4 is a timing chart illustrating an operation of each light emitting element according to the embodiment.

FIG. 5 is a diagram for describing changes in temperature of light emitting elements in the embodiment and a reference example.

FIG. 6 is a timing chart illustrating an operation of each light emitting element according to a first variation of the embodiment.

FIG. 7 is a timing chart illustrating an operation of each light emitting element according to a second variation of the embodiment.

FIG. 8 is a perspective view illustrating a configuration of a light source device according to a third variation of the embodiment.

FIG. 9 is a timing chart illustrating an operation of each light emitting element according to the third variation of the embodiment.

### DESCRIPTION OF EMBODIMENTS

Embodiments of a light source device disclosed in the present application will be described in detail below with reference to the accompanying drawings. Note that the present invention is not limited to the embodiments that will be described below.

A light source device in which a plurality of light emitting elements such as laser diodes are mounted is known. However, in a conventional light source device, since the light emitting element is prone to heat generation during operation, the temperature of the light emitting element tends to increase due to heat generation of the light emitting device itself and thermal interference from other adjacent light emitting elements.

Since a light emitting frequency of the light emitting element tends to change due to such an increase in temperature, there is a problem in that the light emission output of the light source device is not stable.

Accordingly, the above-described problems are expected to be overcome to realize a light source device capable of suppressing an increase in the temperature of the light emitting element.

### Configuration of Light Source Device

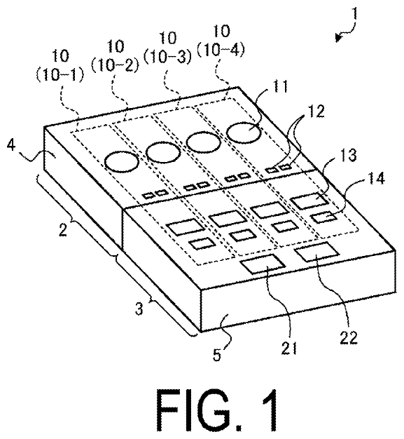

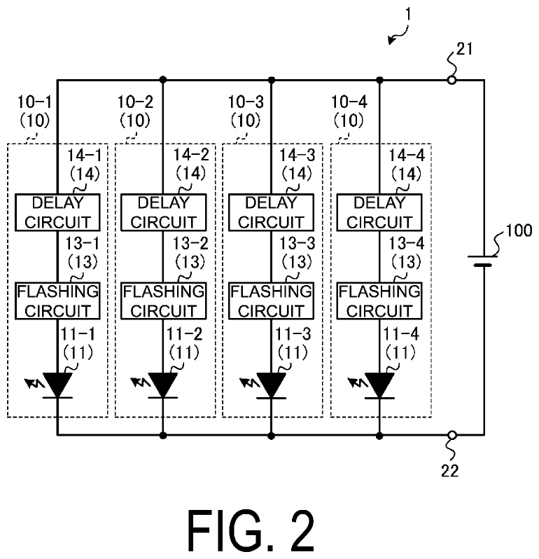

First, a configuration of a light source device 1 according to an embodiment will be described with reference to FIGS. 1 and 2. FIG. 1 is a perspective view illustrating a configuration of the light source device 1 according to the embodiment, and FIG. 2 is a circuit diagram illustrating a configuration of the entirety of the light source device 1 according to the embodiment.

As illustrated in FIG. 1, the light source device 1 according to the embodiment includes a light emitting unit 2 and a drive unit 3. The light emitting unit 2 is a portion provided in a substrate 4, and includes a plurality (four in the drawing) of light emitting elements 11 and a plurality (four pairs in the drawing) of external terminals 12.

The drive unit 3 is a portion provided in a substrate 5, and includes a plurality (four in the drawing) of flashing circuits 13, a plurality (four in the drawing) of delay circuits 14, and electrodes 21 and 22.

In the example illustrated in FIG. 1, the substrate 4 (in other words, the light emitting unit 2) of the light source device 1 and the substrate 5 (in other words, the drive unit 3) are in contact with each other. However, the substrate 4 and the substrate 5 need not be in contact with each other in the light source device 1, and the light source device 1 may be formed with the substrate 4 and the substrate 5 being separated from each other.

Each of the plurality of light emitting elements 11 is formed of, for example, a light emitting diode (LED), a semiconductor laser diode (LD), or the like. The light emitting element 11 emits light by a predetermined current being supplied to a corresponding pair of external terminals 12.

The substrate 4 functions as a support body configured to support the plurality of light emitting elements 11 and functions as a heat dissipation body configured to dissipate heat generated by the plurality of light emitting elements 11 to the outside.

The flashing circuit 13 is a circuit configured to cause the light emitting element 11 to flash by switching on and off a current supply to the light emitting element 11. The flashing circuit 13 causes the light emitting element 11 to flash at a predetermined cycle and duty ratio. A detailed circuit configuration of such a flashing circuit 13 will be described below.

Each of the plurality of delay circuits 14 controls a timing at which the flashing circuit 13 causes the light emitting element 11 to flash by delaying an operation of the flashing circuit 13 by a predetermined period of time. A detailed circuit configuration of the delay circuit 14 will be described below.

As illustrated in FIG. 1, one light emitting unit portion 10 includes one light emitting element 11, a pair of external terminals 12, one flashing circuit 13, and one delay circuit 14, which are provided in the light source device 1. In other words, the light emitting unit portion 10 is formed as one unit including the light emitting element 11, the flashing circuit 13, and the delay circuit 14. In the example illustrated in FIG. 1, four light emitting unit portions 10-1 to 10-4 are provided in the light source device 1.

As illustrated in FIG. 2, the four light emitting unit portions 10-1 to 10-4 are connected to each other in parallel between the electrode 21 and the electrode 22. In each light emitting unit portion 10, the delay circuit 14, the flashing circuit 13, and the light emitting element 11 are connected to each other in series in this order between the electrode 21 and the electrode 22.

A positive electrode of a power supply 100, which is a direct current power supply, is connected to the electrode 21, and a negative electrode of the power supply 100 is connected to the electrode 22, so that a predetermined current is supplied to a light emitting element 11-1 via a delay circuit 14-1 and a flashing circuit 13-1 in the light emitting unit portion 10-1.

The power supply 100 is connected to the electrodes 21 and 22, so that a predetermined current is supplied to a light emitting element 11-2 via a delay circuit 14-2 and a flashing circuit 13-2 in the light emitting unit portion 10-2, and a predetermined current is supplied to a light emitting element 11-3 via a delay circuit 14-3 and a flashing circuit 13-3 in the light emitting unit portion 10-3.

In addition, the power supply 100 is connected to the electrodes 21 and 22, so that a predetermined current is supplied to a light emitting element 11-4 via a delay circuit 14-4 and a flashing circuit 13-4 in the light emitting unit portion 10-4.

### Circuit Configuration of Light Emitting Unit Portion

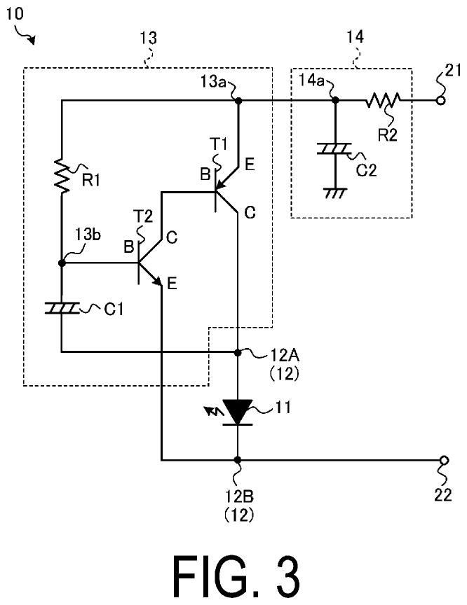

Next, a circuit configuration of the light emitting unit portion 10 will be described with reference to FIG. 3. FIG. 3 is a circuit diagram illustrating a configuration of the light emitting unit portion 10 according to the embodiment. As described above, the light emitting unit portion 10 includes the light emitting element 11, the external terminal 12, the flashing circuit 13, and the delay circuit 14.

The light emitting element 11 is, for example, a light emitting diode. Note that the light emitting element 11 is not limited to the light emitting diode, and may be, for example, a semiconductor laser or the like.

An anode of the light emitting element 11, which is a diode, is connected to an external terminal 12A, which is one external terminal 12, and a cathode of the light emitting element 11 is connected to an external terminal 12B, which is the other external terminal 12. The external terminal 12B is connected to the electrode 22.

The flashing circuit 13 includes a transistor T1, which is a PNP transistor, a transistor T2, which is an NPN transistor, a resistor R1, and a capacitor C1. The delay circuit 14 includes a resistor R2 and a capacitor C2.

The resistor R2 in the delay circuit 14 is connected between the electrode 21 and a node 14a. The capacitor C2 of the delay circuit 14 is connected between the node 14a and a ground potential. The node 14a of the delay circuit 14 is connected to a node 13a of the flashing circuit 13.

An emitter of the transistor T1 in the flashing circuit 13 is connected to the node 13a, a collector of the transistor T1 is connected to the external terminal 12A, and a base of the transistor T1 is connected to a collector of the transistor T2.

An emitter of the transistor T2 in the flashing circuit 13 is connected to the external terminal 12B, and a base of the transistor T2 is connected to a node 13b.

The resistor R1 in the flashing circuit 13 is connected between the node 13a and the node 13b. The capacitor C1 in the flashing circuit 13 is connected between the node 13b and the external terminal 12A.

In the light emitting unit portion 10 according to the embodiment, the delay circuit 14 has a function of supplying current supplied from the power supply 100 (see FIG. 2) via the electrode 21 to the flashing circuit 13 via the node 14a and the node 13a. The delay circuit 14 controls a timing at which the current supplied from the power supply 100 is supplied to the flashing circuit 13.

Specifically, a charging time of the capacitor C2 is adjusted by a resistance value of the resistor R2 and a capacitance value of the capacitor C2 in the delay circuit 14 being adjusted. Accordingly, a timing of the current supply from the delay circuit 14 to the flashing circuit 13, which is started after the capacitor C2 has been charged, can be controlled.

The timing at which the current is supplied from the delay circuit 14 to the flashing circuit 13 can be delayed by the resistance value of the resistor R2 being increased, for example. Similarly, the timing at which the current is supplied from the delay circuit 14 to the flashing circuit 13 can be delayed by the capacitance value of the capacitor C2 being increased.

Conversely, the timing at which the current is supplied from the delay circuit 14 to the flashing circuit 13 can be advanced by the resistance value of the resistor R2 being decreased. Similarly, the timing at which the current is supplied from the delay circuit 14 to the flashing circuit 13 can be advanced by the capacitance value of the capacitor C2 being decreased.

When the capacitor C2 is charged and current starts to be supplied to the node 13a of the flashing circuit 13, the charging to the capacitor C1 via the resistor R1 is started. Then, when the charging of the capacitor C2 ends, current starts to be supplied to the base of the transistor T2 via the resistor R1.

As a result, in the flashing circuit 13, current flows easily between the base and emitter and between the collector and emitter of the transistor T2. Accordingly, current flows easily between the base and emitter, between the emitter and collector, and between the base and collector of the transistor T1 connected to the collector of the transistor T2.

As a result, current starts to be supplied to the light emitting element 11 via the node 13a and the transistor T1, so that the lighting of the light emitting element 11 is started.

Then, when the lighting of the light emitting element 11 is started, the current supplied via the node 13a concentrates on a wiring on the light emitting element 11 side rather than on a wiring on the resistor R1 side. This is because an internal resistance of the light emitting element 11 is smaller than the resistance value of the resistor R1. In other words, when the lighting of the light emitting element 11 is started, the supply of current to the capacitor C1 (in other words, the charging to the capacitor C1) is stopped.

Then, when the supply of current to the capacitor C1 is stopped, the supply of current from the capacitor C1 to the transistor T2 is maintained until a predetermined period of time (a period of time until discharge of the capacitor C1 is completed) has elapsed. However, when the predetermined period of time has passed, the supply of current to the transistor T2 is stopped and the transistor T2 is in an off state.

Then, when the transistor T2 is in the off state, the supply of current to the transistor T1 is stopped, and the transistor T1 is also in the off state. As a result, the current supply to the light emitting element 11 is stopped, and, consequently, the light emitting element 11 is turned off. Thereafter, as described above, the charging from the power supply 100 to the capacitor C1 is started again.

In other words, in the flashing circuit 13 according to the embodiment, (1) charging of the capacitor C1, (2) conduction of the transistors T2 and T1, (3) lighting of the light emitting element 11, (4) discharging of the capacitor C1, (5) disconnection of the transistors T2 and T1, and (6) the turning off of the light emitting element 11 are sequentially repeated. In this way, the flashing circuit 13 according to the embodiment can repeatedly cause the light emitting element 11 to flash.

The light emitting unit portion 10 according to the embodiment can cause the light emitting element 11 to flash at a desired timing, cycle, and duty ratio by appropriately adjusting the resistance values of the resistors R1 and R2 and the capacitance values of the capacitors C1 and C2.

As described above, in the light emitting unit portion 10 according to the embodiment, the desired timing, cycle, and duty ratio can be set by passive elements such as the resistors R1 and R2, and the capacitors C1 and C2. Accordingly, according to the embodiment, such a desired timing, cycle, and duty ratio can be accurately and simply set.

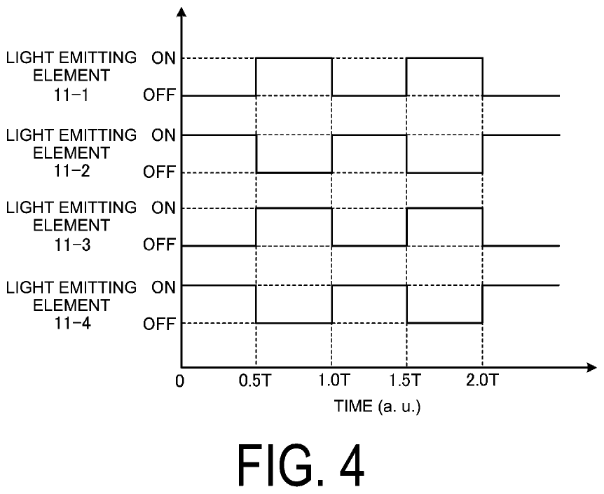

Note that the circuit configurations of the flashing circuit 13 and the delay circuit 14 according to the embodiment are not limited to the example in FIG. 4, and any circuit configuration may be employed as long as the circuit is capable of causing the light emitting element 11 to flash at a desired timing, cycle, and duty ratio.

### Operation of Light Source Device

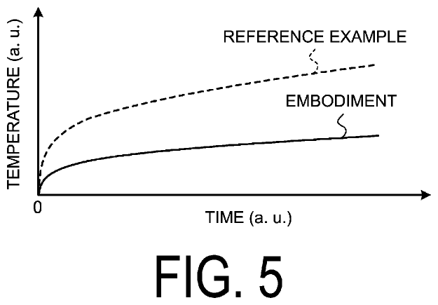

Next, an operation of the light source device 1 according to the embodiment will be described with reference to FIGS. 4 and 5. FIG. 4 is a timing chart illustrating an operation of each of the light emitting elements 11 according to the embodiment.

As illustrated in FIG. 4, in the light source device 1 according to the embodiment, light emission cycles of the four light emitting elements 11-1 to 11-4 are aligned to the same cycle (the cycle 1.0 Tin the drawing), and the duty ratios are all set to 50%.

In the light source device 1 according to the embodiment, at least one of the resistance value of the resistor R2 (see FIG. 3) and the capacitance value of the capacitor C2 (see FIG. 3), included in the delay circuit 14, is made different among the light emitting elements 11 in the at least two light emitting unit portions 10.

As a result, as illustrated in FIG. 4, the timings at which the light emitting elements 11 of at least two light emitting unit portions 10 flash can be made different from each other.

Thus, according to the embodiment, the time during which the light emitting elements 11 are lit as the entirety of the light source device 1 can be made longer than the duty ratio. Furthermore, according to the embodiment, as illustrated in FIG. 5, an increase in the temperature of the light emitting element 11 can be suppressed by pulse driving as compared with a reference example in which the light emitting element 11 is made to emit light by continuous energization from a direct current power supply. FIG. 5 is a diagram illustrating changes in temperature of the light emitting elements 11 in the embodiment and the reference example.

Note that in the example in FIG. 5, provided that a temperature 10 seconds after the start of energization of the light emitting element 11 in the reference example was 1, a temperature 10 seconds after the start of the energization of the light emitting element 11 according to the embodiment was 0.44 (the flashing cycle of the light emitting elements 11 was 25 Hz).

In the embodiment, the power consumption of the light emitting element 11 can be reduced by pulse driving the light emitting element 11.

In the embodiment, the light emitting elements 11 can be continuously lit as the entirety of the light source device 1 by alternating a lighting period and a lighting off period between the light emitting elements 11 of the at least two light emitting unit portions 10.

In the embodiment, a deviation of an accumulated lighting time among the light emitting elements 11 can be reduced by the duty ratio of the light emitting elements 11, in which the lighting period and the lighting off period alternate, being set to 50%. Thus, according to the embodiment, the life of the light source device 1 can be extended.

In the embodiment, a CR product (a product of the resistance value of the resistor R2 and the capacitance value of the capacitor C2) of the delay circuit 14 is preferably 0.028 seconds or less among the light emitting elements 11 of the at least two light emitting unit portions 10.

As a result, the flashing cycle of the light emitting elements 11 can be 0.028×1.4=0.0392 seconds or less, so that the flashing frequency of the light emitting elements 11 can be 25 Hz or more.

Thus, according to the embodiment, even when the light emitting elements 11 are caused to flash, the light emitting elements 11 can be made to appear to illuminate as continuous light.

For example, in the light emitting unit portions 10-1 and 10-3, the resistance values of the resistors R1 and R2 are set to 33 kΩ, and the capacitance values of the capacitors C1 and C2 are set to 1.73 μF. In the light emitting unit portions 10-2 and 10-4, the resistance values of the resistors R1 and R2 are set to 33 kΩ, and the capacitance values of the capacitors C1 and C2 are set to 3.46 μF.

As a result, the light emission timing as illustrated in FIG. 4 can be set for each of the light emitting elements 11-1 to 11-4, and the flashing frequency of each of the light emitting elements 11-1 to 11-4 can be 25 Hz.

In the embodiment, at least one of the resistance value of the resistor R2 and the capacitance value of the capacitor C2 is preferably made different between the light emitting elements 11 (for example, the light emitting element 11-1 and the light emitting element 11-2) of the at least two adjacent light emitting unit portions 10.

As a result, as illustrated in FIG. 4, the timings at which the light emitting elements 11 of the adjacent light emitting unit portions 10 flash can be made different from each other.

Accordingly, according to the embodiment, since the adjacent light emitting elements 11 can be alternately made to emit light, an unevenness of a light of a display surface can be reduced when, for example, the light source device 1 is used as a backlight of the display.

In the embodiment, since the adjacent light emitting elements 11 can be alternately made to emit light, thermal interference from the adjacent light emitting elements 11 can be reduced. Thus, according to the embodiment, an increase in the temperature of the light emitting elements 11 can be further suppressed.

In the embodiment, the CR product of the delay circuit 14 is preferably 0.028 seconds or less among the light emitting elements 11 in the at least two adjacent light emitting unit portions 10.

As a result, the flashing frequency of the two adjacent light emitting elements 11 can be 25 Hz or more. Thus, according to the embodiment, the two adjacent light emitting elements 11 can be made to appear to illuminate as continuous light.

In the embodiment, at least one of the resistance value of the resistor R2 and the capacitance value of the capacitor C2 is preferably made different between the light emitting elements 11 of all of the light emitting unit portions 10 adjacent to each other.

As a result, as illustrated in FIG. 4, the timings at which the light emitting elements 11 of all of the light emitting unit portions 10 adjacent to each other flash can be made different from each other. Accordingly, according to the embodiment, since all of the light emitting elements 11 adjacent to each other can be alternately made to emit light, the unevenness of the light of the display surface can be further reduced when the light source device 1 is used as the backlight of the display.

In the embodiment, since all of the light emitting elements 11 adjacent to each other can be alternately made to emit light, the thermal interference from the adjacent light emitting elements 11 can be further reduced. Thus, according to the embodiment, an increase in the temperature of the light emitting elements 11 can be further suppressed.

### Various Variations

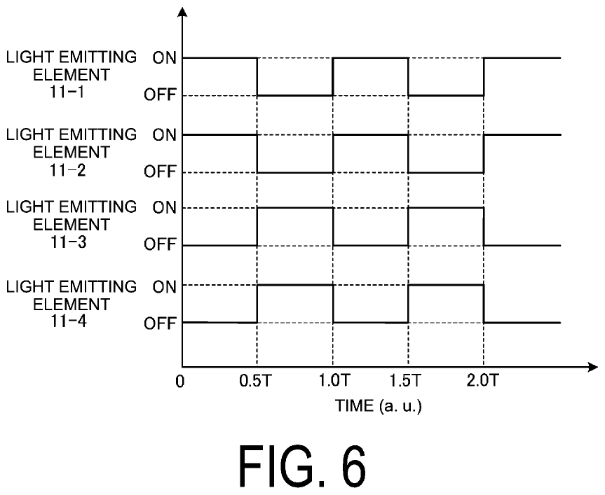

Various variations of the light source device 1 according to the embodiment will be described with reference to FIGS. 6 to 9. FIG. 6 is a timing chart illustrating an operation of each of the light emitting elements 11 according to a first variation of the embodiment.

Note that, in the various variations below, redundant explanations are omitted, with parts that are the same as those in the embodiment described above denoted by the same reference numerals.

As illustrated in FIG. 6, in the light source device 1 of the first variation, the light emitting element 11-1 and the light emitting element 11-2 adjacent to each other are caused to flash in synchronization with each other, and the light emitting element 11-3 and the light emitting element 11-4 adjacent to each other are caused to flash in synchronization with each other.

By making at least one of the resistance value of the resistor R2 and the capacitance value of the capacitor C2 in the delay circuit 14 different between the light emitting elements 11-2 and the light emitting elements 11-3 adjacent to each other, the timings at which the light emitting element 11-2 and the light emitting element 11-3 flash are made different from each other.

As a result, an increase in the temperature of the light emitting elements 11 can be suppressed, and the time during which the light emitting elements 11 are lit as the entirety of the light source device 1 can be made longer.

In the first variation, since the lighting period and the lighting off period alternate between the light emitting element 11-1 (or the light emitting element 11-2) and the light emitting element 11-3 (or the light emitting element 11-4), the light emitting elements 11 can be continuously lit as the entirety of the light source device 1.

In the first variation, since the adjacent light emitting elements 11-2 and the light emitting element 11-3 are alternately made to emit light, the unevenness of the light of the display surface can be reduced when the light source device 1 is used as the backlight of the display.

Note that in the above-described embodiment and the first variation, an example is described in which two of the four light emitting unit portions 10 are caused to flash in synchronization with each other, but each of the two of the four light emitting unit portions 10 need not be in synchronization with each other. For example, the four light emitting unit portions 10 may be divided into three light emitting unit portions 10 flashing in synchronization with each other and one light emitting unit portion 10 flashing at a timing different from thereof.

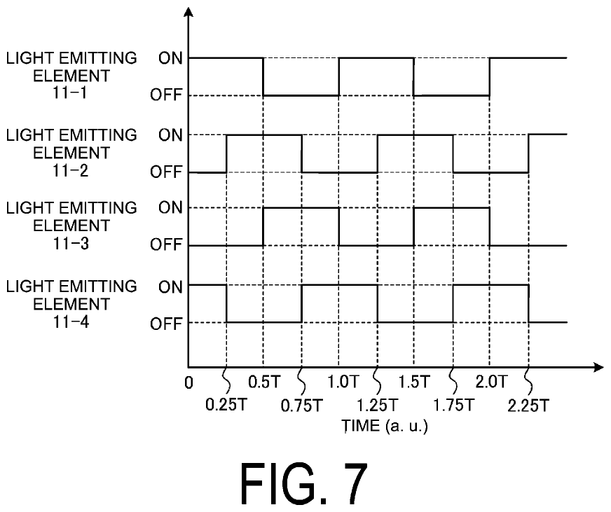

In the above-described embodiment and the first variation, an example is described in which the light emitting elements 11 of the at least two light emitting unit portions 10 are caused to flash with a shift of ½ cycle (0.5 T), but the cycle of shifting the flashing is not limited to ½ cycle. FIG. 7 is a timing chart illustrating an operation of each of the light emitting elements 11 according to a second variation of the embodiment.

As illustrated in FIG. 7, in the light source device 1 according to the second variation, by making at least one of the resistance value of the resistor R2 and the capacitance value of the capacitor C2 in each of light emitting unit portions 10 different from each other, the light emitting element 11 of each of the light emitting unit portions 10 is caused to flash with a shift of ¼ cycle (0.25 T).

As a result, an increase in the temperature of the light emitting elements 11 can be suppressed, and the time during which the light emitting elements 11 are lit as the entirety of the light source device 1 can be made longer.

In the second variation, since any one of the light emitting elements 11 is continuously lit, the light emitting elements 11 can be continuously lit as the entirety of the light source device 1. Note that the time for shifting the emission timing of the light emitting element 11 is not limited to the above-described ½ cycle or ¼ cycle.

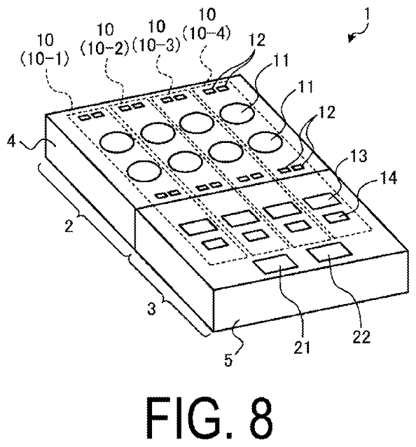

FIG. 8 is a perspective view illustrating a configuration of a light source device 1 according to a third variation of the embodiment. As illustrated in FIG. 8, in the third variation, a plurality (two in the drawing) of light emitting elements 11 are provided in one light emitting unit portion 10.

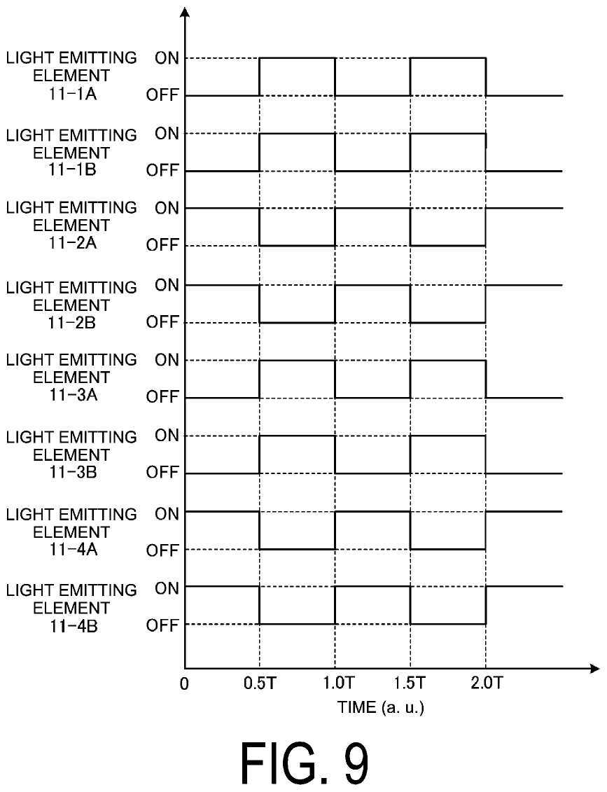

FIG. 9 is a timing chart illustrating an operation of each of the light emitting elements 11 according to the third variation of the embodiment. Note that in FIG. 9, the two light emitting elements 11 provided in the light emitting unit portion 10-1 (see FIG. 8) are respectively denoted by light emitting elements 11-1A and 11-1B, and the light emitting elements 11 provided in the light emitting unit portions 10-2 to 10-4 (see FIG. 8) are similarly denoted.

As illustrated in FIG. 9, in the third variation, the plurality of light emitting elements 11 provided in the same light emitting unit portion 10 flash in synchronization with each other. In the light source device 1 according to the third variation, at least one of the resistance value of the resistor R2 (see FIG. 3) and the capacitance value of the capacitor C2 (see FIG. 3) included in the delay circuit 14, is made different among the at least two light emitting unit portions 10.

As a result, as illustrated in FIG. 9, the timings at which the light emitting elements 11 of at least two light emitting unit portions 10 flash can be made different from each other. Thus, according to the third variation, an increase in the temperature of the light emitting elements 11 can be suppressed, and the time during which the light emitting elements 11 are lit as the entirety of the light source device 1 can be made longer.

In the third variation, as illustrated in FIG. 9, the light emitting elements 11 can be continuously lit as the whole light source device 1 by the lighting period and the lighting off period alternating between the light emitting elements 11 of the at least two light emitting unit portions 10.

In the third variation, the deviation of the accumulated lighting time among the light emitting elements 11 can be reduced by the duty ratio of the light emitting elements 11, in which the lighting period and the lighting off period alternate, being set to 50%. Thus, according to the third variation, the life of the light source device 1 can be extended.

In the third variation, the CR product of the delay circuit 14 is preferably 0.028 seconds or less among the light emitting elements 11 in the at least two light emitting unit portions 10. As a result, the flashing frequency of the light emitting elements 11 in the at least two light emitting unit portions 10 can be 25 Hz or more.

Thus, according to the third variation, the light emitting elements 11 in the at least two light emitting unit portions 10 can be made to appear to illuminate as continuous light. Note that in the third variation, the number of the light emitting elements 11 provided in one light emitting unit portion 10 is not limited to two, and three or more light emitting elements 11 may be provided in one light emitting unit portion 10.

Although embodiments of the present disclosure are described above, the present disclosure is not limited to the embodiments described above, and various modifications can be made without departing from the spirit thereof. For example, in the above-described embodiment, an example is described in which the four light emitting unit portions 10 are provided in the light source device 1, but the number of the light emitting unit portions 10 provided in the light source device 1 is not limited to four.

For example, in consideration of an improvement in the amount of light and suppression of power consumption in the light source device 1, the number of light emitting unit portions 10 provided in the light source device 1 is preferably 10 or more and 30 or less.

In the above-described embodiment, an example is described in which the duty ratio of the light emitting elements 11 flashing by the flashing circuit 13 is set to 50%; however, the duty ratio of the light emitting elements 11 set by the flashing circuit 13 is not limited to 50%.

As described above, the light source device 1 according to the embodiment includes the plurality of light emitting unit portions 10 each including the light emitting elements 11, the flashing circuit 13 configured to cause the light emitting elements 11 to flash, and the delay circuit 14 configured to control the timing at which the flashing circuit 13 causes the light emitting elements 11 to flash. The delay circuit 14 includes the resistor R2 and the capacitor C2. At least two light emitting unit portions 10 are connected to each other in parallel. At least one of the resistance value of the resistor R2 and the capacitance value of the capacitor C2 differs among the at least two light emitting unit portions 10 connected to each other in parallel. As a result, an increase in the temperature of the light emitting elements 11 can be suppressed.

In the light source device 1 according to the embodiment, the CR product of the delay circuit 14 is 0.028 seconds or less in the at least two light emitting unit portions 10 connected to each other in parallel. As a result, the light emitting elements 11 can be made to appear to illuminate as continuous light.

In the light source device 1 according to the embodiment, two light emitting unit portions 10 connected to each other in parallel are disposed adjacent to each other, and at least one of the resistance value of the resistor R2 and the capacitance value of the capacitor C2 differs between the two light emitting unit portions 10 disposed adjacent to each other. As a result, unevenness of the light of the display surface can be reduced when, for example, the light source device 1 is used as the backlight of the display.

In the light source device 1 according to the embodiment, the CR product of the delay circuit 14 is 0.028 seconds or less in the two light emitting unit portions 10 disposed adjacent to each other. As a result, the two adjacent light emitting elements 11 can be made to appear to illuminate as continuous light.

In the light source device 1 according to the embodiment, the light emitting unit portion 10 includes the plurality of light emitting elements 11 configured to flash in synchronization with each other. At least one of the resistance value of the resistor R2 and the capacitance value of the capacitor C2 differs among the at least two light emitting unit portions 10 including the plurality of light emitting elements 11 emitting light in synchronization with each other. As a result, an increase in the temperature of the light emitting elements 11 can be suppressed.

The disclosed embodiments should be considered as illustrative and not limiting in any point. In fact, the embodiments described above can be embodied in a variety of forms. Omission, replacement, and change can be made in various forms on the above embodiments without departing from the scope and the spirit of the appended claims.

### REFERENCE SIGNS LIST

1 Light source device
10, 10-1 to 10-4 Light emitting unit portion
11, 11-1 to 11-4 Light emitting element
13, 13-1 to 13-4 Flashing circuit
14, 14-1 to 14-4 Delay circuit
R2 Resistor
C2 Capacitor

1. A light source device comprising:
a plurality of light emitting unit portions, each light emitting unit portion of the plurality of light emitting unit portions comprising a light emitting element, a flashing circuit configured to cause the light emitting element to flash, and a delay circuit configured to control a timing at which the flashing circuit causes the light emitting element to flash; wherein
the delay circuit comprises a resistor and a capacitor,
at least two light emitting unit portions of the plurality of light emitting unit portions are connected to each other in parallel, and
at least one of a resistance value of the resistor and a capacitance value of the capacitor differs among the at least two of the light emitting unit portions connected to each other in parallel.

2. The light source device according to claim 1, wherein
a CR product of the delay circuit is 0.028 seconds or less in the at least two light emitting unit portions connected to each other in parallel.

3. The light source device according to claim 1, wherein
the at least two light emitting unit portions connected to each other in parallel are disposed adjacent to each other, and
the at least one of the resistance value of the resistor and the capacitance value of the capacitor differs between the at least two light emitting unit portions disposed adjacent to each other.

4. The light source device according to claim 3, wherein
the CR product of the delay circuit is 0.028 seconds or less in the at least two light emitting unit portions disposed adjacent to each other.

5. The light source device according to claim 1, wherein
a plurality of light emitting elements comprising the light emitting element of the each light emitting unit portion of the plurality of light emitting unit portions are configured to flash in synchronization with each other, and
the at least one of the resistance value of the resistor and the capacitance value of the capacitor differs among the at least two light emitting unit portions comprising the plurality of the light emitting elements configured to flash in synchronization with each other.
